(19) United States
(12) Patent Application Publication
(10) Pub. No.: US 2025/0374868 A1
(43) Pub. Date: Dec. 11, 2025

(54) Monitoring Apparatus for Monitoring a Treatment Apparatus for Crops

(71) Applicant: crop.zone GmbH, Aachen (DE)

(72) Inventor: Fabian Effey, Aachen (DE)

(21) Appl. No.: 18/872,819

(22) PCT Filed: May 12, 2023
(86) PCT No.: PCT/EP2023/062819

§ 371 Date: Dec. 7, 2024

(30) Foreign Application Priority Data
Jun. 10, 2022 (DE) 10 2022 114 636.7

(51) Int. Cl. A01G 7/04; G01R 19/165

(52) U.S. Cl. CPC A01G 7/04; G01R 19/16576

(57) ABSTRACT

The invention relates to a method for treating plants, having the steps: (S100) detecting a value indicative of a step size voltage (SWS) of a treatment device (1) for treating plants, (S200) comparing the value indicative of a step size voltage (SWS) with a limit value (GW), and (S300) providing at least one actuation signal (AS) for switching off the treatment device (1) in a safety-oriented manner if violation of the limit value (GW) is detected.

### CROSS REFERENCE TO RELATED APPLICATION

This application is a U.S. National Stage entry under 35 U.S.C. § 371 based on International Application No. PCT/EP2023/062819, filed on May 12, 2023, which was published under PCT Article 21(2) and which claims priority from German Application No. 102022114636.7, filed on Jun. 10, 2022. The disclosure of each of the foregoing documents is incorporated herein by reference.

### TECHNICAL FIELD

The invention relates to a method, a computer program product, and a monitoring device for monitoring a treatment device for treating plants, in particular for desiccating field crops, for green manure control or for weed control. Furthermore, the invention relates to a carrier vehicle having a monitoring device of this kind and a kit containing components of a monitoring device of this kind.

### BACKGROUND

Desiccation (dry-down) is a procedure in agriculture in which crop plants are killed with desiccants for the purpose of accelerating ripening. It facilitates harvesting and promotes the ripening of arable crops. This procedure mimics the natural desiccation process of wilting of cultivated plants when the fruit ripens, in which the green parts of the plant above ground turn brown. A welcome side effect is the simultaneous killing of weeds, the still green plant parts of which would otherwise be harvested, for example, with cereals and would increase the moisture content of the crop.

Field crops or arable crops are cultivated plants that are grown in fields. Field crops include, for example, cereals, root crops and legumes, oil crops or plants for green harvesting, which are used as animal feed or, like silage maize, for energy production.

Green manuring is a natural method in agriculture to cover and improve the soil. It refers to the incorporation of green plants or wilted plant material (harvest residues, etc.) into the soil. Catch crops can also be used for this purpose. A catch crop is a field crop that is grown between other main field crops predominantly to be used as green manure or for use as animal feed. Unlike crops, the plants are usually not harvested, but mulched or plowed under.

If electric current flows through plant parts, they are damaged as a function of electric current strength, electric voltage, current type (direct current, alternating current, frequency, degree of smoothing or residual ripple, etc.). A comprehensive and uniform theory of the effect has not been present until now. It can be safely assumed that in particular the conductive bundles for transporting liquid in the plant, as the parts with the lowest electric resistance, are damaged in such a manner that they become non-functional and the plant subsequently dies and withers, depending on the degree of damage and the weather conditions.

The use of direct electric current for treating plants is known, for example, from U.S. Pat. No. 2,007,383 and WO 2019/052591 A1, while the use of direct electric current or alternating electric current is known, for example, from WO 2018/095450 A1 or WO 2018/050142 A1.

WO 2016/162667 A1 discloses another method and another device for the electro-treatment of plants.

Traditionally, two metallic applicators are used when applying electric current to plants, at least to keep the electric resistance at the contact point as low as possible.

Such applicators are also referred to as long applicators (long range applicators, also tongue applicators or LRBs (“long range blade”)). Such applicators have a distance of 0.8 m to 1 m, for example. However, short applicators (SRA, short range blade) can also be used, with a distance in the range of 0.1 m to 0.5 m.

Furthermore, in some cases the circuit is closed not by a second contact on plants with the opposite pole, but by electrodes cutting into the soil.

The use of high electric voltages requires wide clearances and barriers for reasons of occupational safety. This is especially true when metallic conductors are present in the work region, e.g., in a vineyard or in urban applications. Such devices are correspondingly expensive due to elaborate insulation and are disadvantageously large due to increased clearance requirements for creepage distances and clearances. The technical and economic applicability is therefore low.

There is therefore a need to identify ways for achieving improvements in occupational safety and, in addition, for providing a possibility for monitoring the operation of the treatment device.

### SUMMARY

The object of the invention is achieved by a method comprising the steps of: detecting a value indicative of a step size voltage of a treatment device for treating plants, comparing the value indicative of a step size voltage with a limit value, and providing at least one actuation signal for switching off the treatment device in a safety-oriented manner if violation of the limit value is detected.

A step size voltage (or step voltage) is generally understood to mean a potential difference (voltage difference) between the two feet of a person who is standing in the region of a ground surface with a voltage gradient. In the present case, a value is detected that is representative of a potential difference between two measuring electrodes that are dragged along the ground. In other words, a value is detected that is characteristic of a voltage distribution or voltage curve generated in the soil by the operation of the treatment device. Such a step size voltage can pose a hazard, in particular for persons in the vicinity of the treatment device. In addition, such a step size voltage can also be detected and evaluated in order to monitor and control the operation of the treatment device.

According to one embodiment, violation of the limit value is detected if the value indicative of a step size voltage is greater than the limit value. The limit value can therefore be understood as an upper limit value. In other words, excessive step size voltages that could pose a hazard to persons in the vicinity of the treatment device are detected.

According to a further embodiment, the value indicative of a step size voltage of the treatment device is measured between two measuring electrodes. In other words, a step size voltage is measured over the predetermined minimum distance between the two measuring electrodes.

The invention further includes a computer program product, a monitoring device for monitoring a treatment device for treating plants, in particular for desiccating field crops or for green manure control, a carrier vehicle having a monitoring device of this kind and a kit containing components of a monitoring device of this kind.

Other embodiments and advantages are described in the detailed description below. This summary does not purport to define the invention. The invention is defined by the claims.

### BRIEF DESCRIPTION OF THE DRAWINGS

The accompanying drawings, where like numerals indicate like components, illustrate embodiments of the invention.

FIG. 1 is a schematic side view of an embodiment of a carrier vehicle having a treatment device for treating plants.

FIG. 2 is a schematic representation of a plan view of the carrier vehicle shown in FIG. 1 having a monitoring device for monitoring the treatment device for treating plants.

FIG. 3 is a schematic perspective view of an applicator unit of the treatment device shown in FIGS. 1-2 with two measuring electrodes of the monitoring device.

FIG. 4 is a schematic representation of a plan view of the applicator unit shown in FIG. 1.

FIG. 5 is a schematic representation of further components of the monitoring device shown in FIG. 2.

FIG. 6 is a schematic representation of a method sequence for operating the carrier vehicle shown in FIGS. 1-2.

### DETAILED DESCRIPTION

Reference will now be made in detail to some embodiments of the invention, examples of which are illustrated in the accompanying drawings.

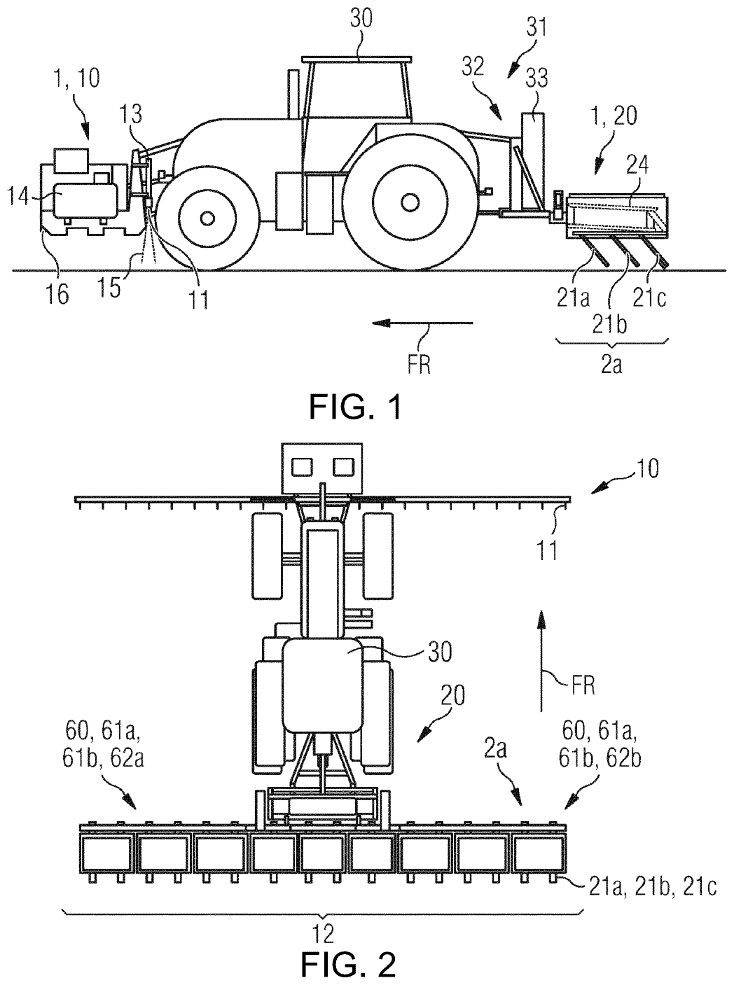

FIG. 1 shows an arrangement of individual components of a treatment device 1 for treating plants on an agricultural machine serving as the carrier vehicle 30.

The treatment device 1 can be used, for example, to bring about desiccation by applying electric current to plants. In this case, provision can be made for electric contact resistances to be reduced by prior application of a contact-resistance-reducing medium 15, such as a corresponding liquid, before the application of electric current.

Agricultural machines are specialized machines which are used predominantly in agriculture. They can be designed to be self-propelled or be drawn by an agricultural tractor vehicle, such as a tractor. In other words, the agricultural machine can be a tractor vehicle with its own drive or a trailer without its own drive, which is pulled by a tractor vehicle.

In the present exemplary embodiment, the carrier vehicle 30 is designed as a tractor. In deviation from the present exemplary embodiment, the carrier vehicle 30 may also be designed as a fertilizer, seed or harvesting machine that has been modified by attaching the components of the treatment device 1. For this purpose, the components of the treatment device 1 may also be provided in the form of a kit.

The treatment device 1 and the carrier vehicle 30 may vary depending on the mode of use and specific requirements of the field crop in question and the time of treatment.

The treatment device 1 may have one or more modules 10, 20, each of which may be designed as an attachment. The treatment device 1 may be designed as a machine/agricultural machine, i.e., as interchangeable equipment consisting of up to two attachments which are mounted simultaneously on the carrier vehicle 30. Furthermore, the treatment device 1 may be designed as interchangeable equipment, i.e., as an device which the operator of the carrier vehicle 30 himself attaches to it after it has been put into operation in order to change or expand its function, provided that this equipment is not a tool.

In the present exemplary embodiment, the treatment device 1 has a first module 10 for applying the contact-resistance-reducing medium 15 and a second module 20 for transmitting direct electric current to plants. In deviation from the present exemplary embodiment, however, the treatment device 1 may also have only a second module 20 for transmitting electric current to the plants. Further, it can be provided that, for example, in the case of a towing/trailing vehicle combination, consisting of a tractor and a trailer pulled by the tractor, the first module 10 is assigned to the tractor vehicle and components of the second module 20 to the trailer. The components of the second module 20 can also be assigned only to the trailer.

In this exemplary embodiment, the contact-resistance-reducing medium 15 is a contact-resistance-reducing liquid.

In the present exemplary embodiment, the first module 10 is arranged on the front side and the second module 20 is arranged on the rear side of the carrier vehicle 30. This arrangement makes it possible for the application of the contact-resistance-reducing medium 15 to always take place before or simultaneously with the electrophysical treatment by applying an electric current, such as direct electric current.

The first module 10 has at least one application device designed as a nozzle 11. In combination with the nozzle 11, the application device can also comprise a wiper (not shown) or alternatively be itself designed as a wiper. The application device is thus designed for spraying and wiping or applying the contact-resistance-reducing liquid 15, or alternatively for spraying or wiping. The first module 10 comprises a number of jointly or preferably individually controllable nozzles 11 or wipers, which are arranged on a first support structure 13 at a desired working width of the treatment device 1 (e.g., 1.5-48 m, preferably 6-27 m) and geometry (statically or flexibly mounted or sensor-controlled in height). The nozzles 11 and/or wipers are supplied with the contact-resistance-reducing medium 15, in the present exemplary embodiment a liquid, which is stored in one or more liquid containers 14. Sensors 16 are located in the region of the nozzles 11, among others (not shown), the data from which is used to control the application amount of the contact-resistance-reducing medium 15 as required. Additional sensors 16 may be located at the front of the first module 10 (i.e., in the direction of travel FR) for the purpose of occupational safety. Sensors used include, but are not limited to, current/voltage sensors, optical sensors such as camera systems, position or movement sensors, LIDAR, metal detectors, and others. Drones flying ahead can also be used to detect plants ahead. Furthermore, pasture fence applicators for deterring or startling animals may be disposed on the carrier vehicle 30 or the second module 20.

In the present exemplary embodiment, the carrier vehicle 30 provides mechanical drive power via a power-take-off (PTO) shaft 31 or hydraulic circuit to an electrical generator 32 of the second module 20, which may be located in the rear region (as shown). The individual modules of the treatment device 1 are arranged as attachments, for example, with three-point suspensions. Special crops require special machines, some of which are already carrier vehicles 30 with special suspensions, if necessary also laterally or under the carrier vehicle 30. In the case of treatment devices 1 with very high power requirements due to, for example, very high working widths or carrier vehicles 30 without sufficient free power capacity, independent power generator systems can also be used, which can be coupled or semi-mounted onto the carrier vehicle 30 or moved on a trailer.

Electric current is conducted from the generator 32 to electric lines to a transformation and control unit 33 of the second module 20. There, the electric current is converted for transformation and then brought to the predetermined electric voltage with a predetermined residual ripple in transformers and other control units positioned centrally or in a distributed manner.

In the present exemplary embodiment, the second module 20 comprises a plurality of applicator units 2a each having a plurality of applicators 21a, 21b, 21c for applying direct electric current to plants.

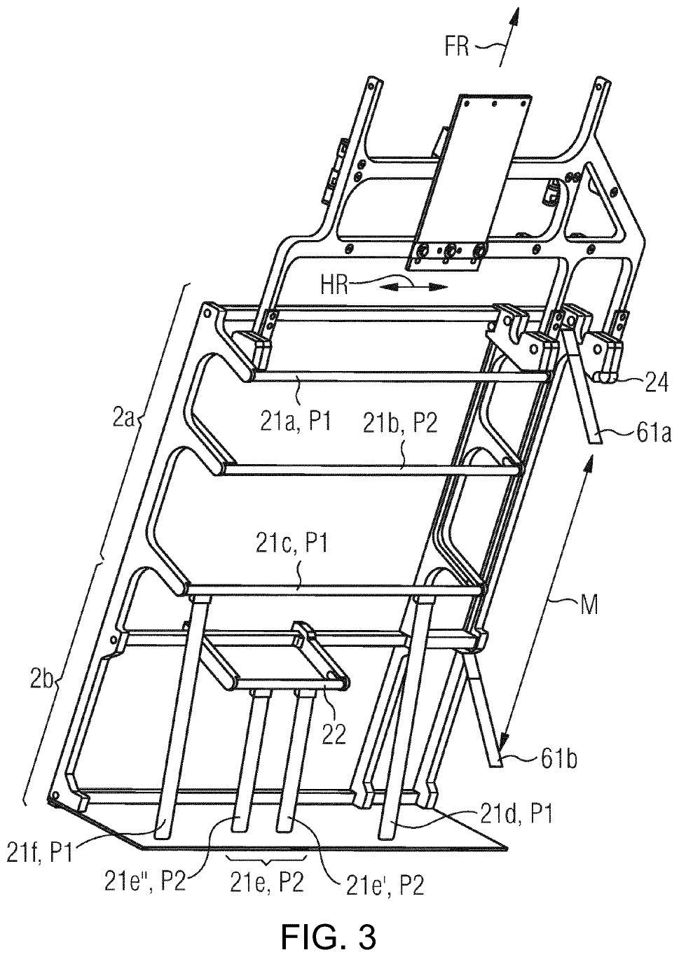

Additionally, reference is now made to FIG. 2.

The plurality of applicator units 2a are arranged in an applicator row 12, the direction of extension of the applicator row 12 extending transversely, in the present exemplary embodiment at an angle of 90°, to a direction of movement FR of the carrier vehicle 30. The applicators 21a, 21b, 21c of the applicator row 12 are arranged on a support structure 24.

A monitoring device 60 is provided in order to reduce the risk of injury, in particular due to electric shocks, during operation of the treatment device 1 and additionally to provide a possibility of monitoring the operation of the treatment device 1.

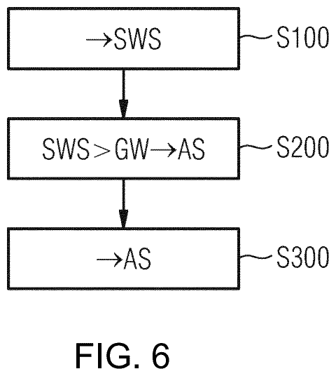

To monitor the treatment device 1, the monitoring device 60 is designed to detect a value indicative of a step size voltage SWS (see FIG. 6) of a treatment device 1 for treating plants, to compare the value indicative of a step size voltage SWS with a limit value GW (see also FIG. 6) and to provide at least one actuation signal AS for switching off the treatment device in a safety-oriented manner (see again FIG. 6) if violation of the limit value GW is detected.

In the present exemplary embodiment, the monitoring device 60 has two measuring electrodes 61a, 61b, which are arranged at the two opposite distal ends 62a, 62b, respectively, of the applicator row 12.

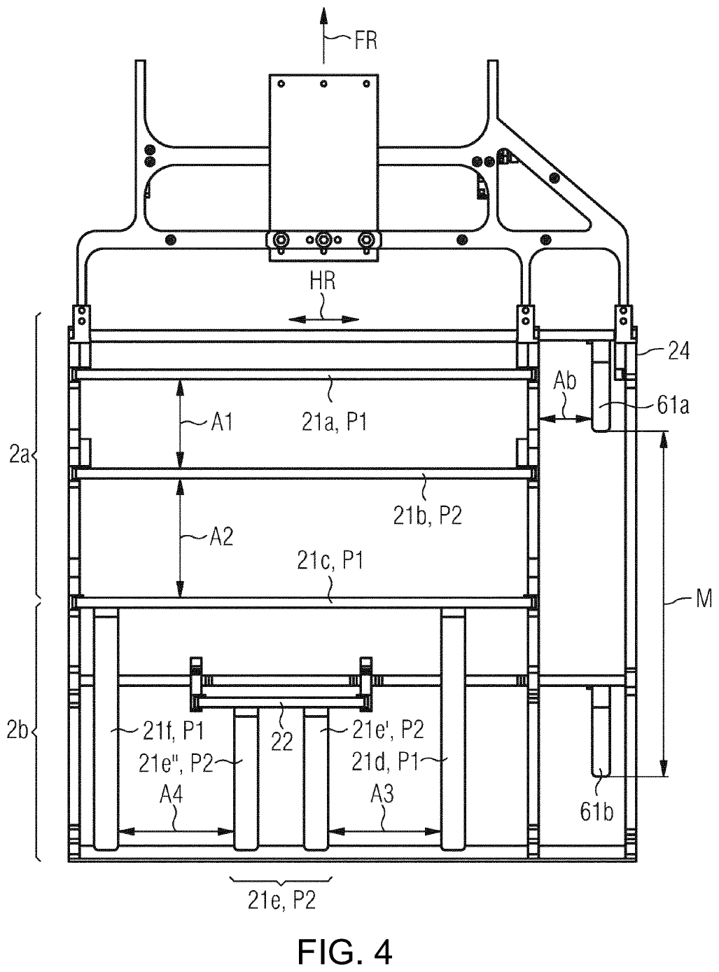

Additionally, reference is now made to FIGS. 3-4. In the present exemplary embodiment, the treatment device 1 as shown comprises, in addition to the first applicator unit 2a, a second applicator unit 2b for applying direct electric current to plants.

The first applicator unit 2a comprises the first, in particular substantially stationarily arranged applicator 21a, the second, in particular substantially stationarily arranged applicator 21b, and the third, in particular substantially stationarily arranged applicator 21c, which are each fastened to the second support structure 24.

In this case, substantially stationarily is understood to mean that, although slight movements of the applicators 21a, 21b, 21c are possible, a distance A1 between the first applicator 21a and the second applicator 21b and a distance A2 between the second applicator 21b and the third applicator 21c, for example, changes only slightly, for example by 3%, 5% or also 10% of the value of the distance A1 or of the value of the distance A2.

In the present exemplary embodiment, the first applicator 21a, the second applicator 21b and the third applicator 21c are arranged in succession at a distance from one another in the direction of the direction of movement FR of the applicator unit 2a with the distance A1 and the distance A2, respectively, from one another.

Furthermore, in the present exemplary embodiment, the first applicator 21a, the second applicator 21b and the third applicator 21c are each rod-shaped with a main direction of extension HR which, in the present exemplary embodiment, extends in a straight line at right angles to the direction of travel FR.

In other words, the first applicator 21a and the third applicator 21c can also be regarded as outer applicators and the second applicator 21b can be regarded as an inner applicator, the outer applicators each having the same polarity P1 and the inner applicator having the other polarity P2.

In the present exemplary embodiment, the first applicator 21a, the second applicator 21b and the third applicator 21c are each designed as round rods made of an electric conductor material. Thus, the first applicator 21a, the second applicator 21b and the third applicator 21c each have a continuously formed outer surface without edges, protrusions or similar surface discontinuities.

The distance A1 between the first applicator 21a and the second applicator 21b as well as the distance A2 between the second applicator 21b and the third applicator 21c may be in the range of 0.1 m to 0.15 m. In the present exemplary embodiment, it is in the range from 15 cm to 20 cm. Applicators of this kind are also referred to as short applicators (SRA—for short range blade). In this embodiment, the distance A1 and the distance A2 are not equal. In the present exemplary embodiment, the distance A1 is smaller than the distance A2. In the present exemplary embodiment, the distance A1 is 15 cm and the distance A2 is 20 cm.

The second applicator unit 2b also has a first, in particular substantially stationarily arranged applicator 21d, a second, in particular substantially stationarily arranged applicator 21e, and a third, in particular substantially stationarily arranged applicator 21f.

In the present exemplary embodiment, the second applicator unit 2b also has a first, in particular substantially stationarily arranged applicator 21d, a second, in particular substantially stationarily arranged applicator 21e, and a third, in particular substantially stationarily arranged applicator 21f, wherein the second applicator 21e, which can be regarded as an inner applicator analogous to the applicator unit 2a, comprises two partial applicators 21e′, 21e″ in the present exemplary embodiment. In addition, a crossbar connecting the two partial applicators 21e′, 21e″ can be regarded as an additional applicator 22 having the same polarity as the two partial applicators 21e′, 21e″.

In the present exemplary embodiment, the first applicator 21d, the two partial applicators 21e′, 21e″ of the second applicator 21e, and the third applicator 21f each have a connection portion and an electrode portion made of an electric conductor material with a free distal end. The respective connection portions and/or electrode portions may be designed to be more flexible than, for example, the applicators 21a, 21b, 21c of the first applicator unit 2a, i.e., they may optionally deform reversibly in the case of soil and/or plant contact.

In the present exemplary embodiment, the first applicator 21d and the third applicator 21f are designed longer than the two partial applicators 21e′, 21e″ of the second applicator 21e. Thus, the first applicator 21d and the third applicator 21f can dip into depressions in the soil on either side of a plant and contact plant stems and/or leaves of the plant located there.

In the present exemplary embodiment, a distance A3 between the first applicator 21d and the partial applicator 21e′ of the second applicator 21e corresponds to the distance A4 between the third applicator 21f and the partial applicator 21e″ of the second applicator 21e. Thus, the distance A3 and the distance A4 are the same in the present exemplary embodiment.

The polarity P1 (plus) is assigned to the respective first applicators 21a, 21c, while the second polarity P2 (minus) is assigned to the applicator 21b. Furthermore, the additional applicator 22 is assigned the polarity P2.

Furthermore, the polarity P1 is assigned to the applicators 21d, 21f, while the polarity P2 is assigned to the applicator 21e with the two partial applicators 21e′, 21e″. This minimizes potential differences between adjacent applicator units 2a, 2b of the applicator row 12 and thus arcing.

FIG. 2 shows two measuring electrodes 61a, 61b of the monitoring device 60, which are assigned to the two applicator units 2a, 2b at the left distal end 62a of the applicator row 12. Accordingly, in the present exemplary embodiment, the monitoring device 60 additionally comprises two further measuring electrodes 61a, 61b, which are assigned to the right distal end 62b of the applicator row 12.

In the present exemplary embodiment, the two measuring electrodes 61a, 61b are arranged at a minimum distance M from one another in the direction of travel FR. The minimum distance M may be in a range of 10 cm to 100 cm, measured from the respective distal ends of the measuring electrodes 61a, 61b. In the present exemplary embodiment, the minimum distance M is 60 cm. In the present exemplary embodiment, the two measuring electrodes 61a, 61b extend over the first applicator unit 2a in the direction of travel FR. Thus, the two measuring electrodes 61a, 61b detect step voltages caused by the first applicator unit 2a. In deviation from the present exemplary embodiment, the two measuring electrodes 61a, 61b may also be aligned differently with respect to the direction of travel FR and/or assigned to the second applicator unit 2b.

Furthermore, in the present exemplary embodiment, the two measuring electrodes 61a, 61b are at a predetermined distance Ab from the two applicator units 2a, 2b transversely to the direction of travel FR. The distance Ab may be in a range of 5 cm to 50 cm. In the present exemplary embodiment, the distance Ab is 10 cm.

In the present exemplary embodiment, the two measuring electrodes 61a, 61b are constructed identically to the electric applicators 21d, 21e, 21f of the second applicator unit 2b. However, in the present exemplary embodiment, the two measuring electrodes 61a, 61b are shorter than the electric applicators 21d, 21e, 21f of the second applicator unit 2b. However, they can also be designed differently. Furthermore, in deviation from the present exemplary embodiment, a selected pair of electric applicators 21a, 21b, 21c may be connected at least temporarily as measuring electrodes 61a, 61b.

In the present exemplary embodiment, the value indicative of a step size voltage SWS is detected using the two measuring electrodes 61a, 61b via the row of electric applicators 21a, 21b, 21c of the applicator row 12. The two measuring electrodes 61a, 61b are therefore not arranged between two ground electrodes to which electrical voltage is applied, i.e., not like in a conventional step size voltage measurement, but rather outside the row of electric applicators 21a, 21b, 21c. In this way, it is also possible to detect and monitor a voltage field which extends laterally, i.e., in the direction of travel FR, to the right or left of the electric applicators 21a, 21b, 21c of the applicator row 12.

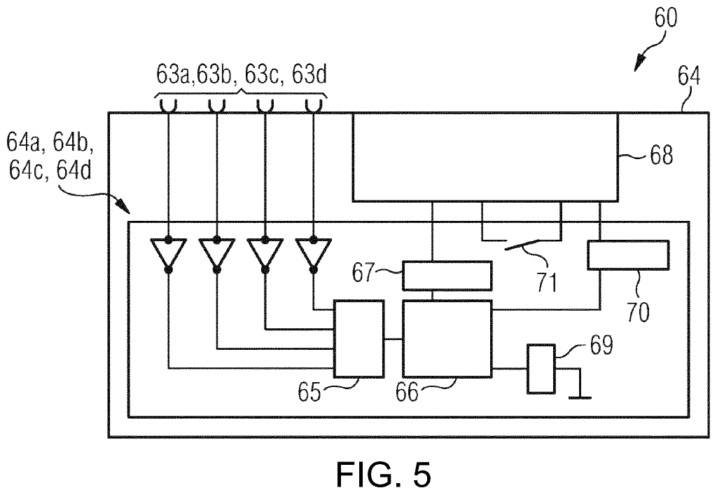

Additionally, reference is now made to FIG. 5.

Further electric components of the monitoring device 60 for monitoring the treatment device 1 for treating plants are shown. In the present exemplary embodiment, these components are received in a housing (not shown) in order to meet protection class IP34 and they form a measuring assembly or measuring box.

The electric components shown are four inputs 63a, 63b, 63c, 63d, which are connected in an electrically conductive manner to the respective measuring electrodes 61a, 61b at the two distal ends 62a, 62b, four operational amplifiers 64a, 64b, 64c, 64d each connected as comparators, an A/D converter 65, a microprocessor 66, an interface 67, a connection 68, an operating power supply 69, an auxiliary power supply 70 and an off switch 71.

In the present exemplary embodiment, the respective connections with the two measuring electrodes 61a, 61b in each case are each designed to be earth-free and/or potential-free.

In particular, the microprocessor 66 may have hardware and/or software components for its tasks and/or functions described below. The microprocessor 66 is designed to detect violation of the limit value GW.

For this purpose, the microprocessor 66 compares the value indicative of a step size voltage SWS with the limit value GW and detects a violation if the value indicative of a step size voltage SWS is greater than the limit value GW. In other words, excessive step size voltages which could pose a hazard for persons in the immediate vicinity of the treatment device 1 are detected.

If the value indicative of a step size voltage SWS is greater than the limit value GW, the microprocessor 66 provides the actuation signal AS, by means of which, for example, the treatment device 1 can be switched off using the off switch 71, which can be actuated via the interface 67 and the connection 68.

In the present exemplary embodiment, the step size voltage SWS is a potential difference (voltage difference) between two of the measuring electrodes 61a, 61b in each case.

An operating power supply 69 and an auxiliary power supply 70 are provided to supply operating power, in particular to the microprocessor 66, while the connection 68 can be used to establish a data- and/or operating-power-transmitting connection with other components of the carrier vehicle 30 and/or the treatment device 1. The connection 68 may, for example, have a USB connection and/or a CAN bus input and/or a CAN bus output and/or a data logger output (ADR) and/or a light display output and/or an actuation signal output and/or an operating power supply connection.

In the present exemplary embodiment, a value of the limit value GW can be set. For example, a value in the range of 10 V to 300 V can be set, wherein it is possible to set the respective values continuously or in 10 V steps, for example.

A method sequence for operating the treatment device 1 together with the monitoring device 60 of the carrier vehicle 30 will now be explained with additional reference to FIG. 6.

For example, upon putting the treatment device 1 into operation, in a first step S100 the value indicative of a step size voltage SWS of the treatment device 1 for treating plants is detected. For this purpose, the four measuring electrodes 60a, 60b in the present exemplary embodiment are used, which are each arranged on the applicator unit 2a, 2b of the treatment device 1.

In a further step S200, the value indicative of the step size voltage SWS is compared with the limit value GW, and in a further step S300 the actuation signal AS is provided if violation of the limit value GW has been detected, i.e., the value indicative of the step size voltage SWS is greater than the limit value GW.

In deviation from the present exemplary embodiment, the sequence of steps may be different. Further, several steps can also be executed simultaneously. Furthermore, individual steps can also be skipped or omitted in deviation from the present exemplary embodiment.

Thus, the monitoring device 60 can increase occupational safety and additionally provides a possibility of monitoring the operation of the treatment device 1.

### REFERENCE NUMERALS

1 Treatment device
2a Applicator unit
2b Applicator unit
10 First module
11 Nozzle
12 Applicator row
13 First support structure
14 Liquid container
15 Contact-resistance-reducing medium
16 Sensor
20 Second module
21a Electric applicator
21b Electric applicator
21c Electric applicator
21d Electric applicator
21e Electric applicator
21e′ Partial applicator
21e″ Partial applicator
21f Electric applicator
22 Additional applicator
24 Second support structure
30 Carrier vehicle
31 PTO shaft
32 Generator
33 Transformation and control unit
60 Monitoring device
61a Measuring electrode
61b Measuring electrode
62a Distal end
62b Distal end
63a Input
63b Input
63c Input
63d Input
64a Operational amplifier
64b Operational amplifier
64c Operational amplifier
64d Operational amplifier
65 A/D converter
66 Microprocessor
67 Interface
68 Connection
69 Operating power supply
70 Auxiliary power supply
71 Off switch
A1 Distance
A2 Distance
A3 Distance
A4 Distance
Ab Distance
AS Actuation signal
FR Direction of travel
GW Limit value
M Minimum distance
SWS Step size voltage
S100 Step
S200 Step
S300 Step

Although the present invention has been described in connection with certain specific embodiments for instructional purposes, the present invention is not limited thereto. Accordingly, various modifications, adaptations, and combinations of various features of the described embodiments can be practiced without departing from the scope of the invention as set forth in the claims.

1.-9. (canceled)

10. A method for treating plants, comprising:
detecting a value indicative of a step size voltage of a treatment device for treating plants;
comparing the value indicative of the step size voltage to a predetermined limit value; and
outputting an actuation signal when the step size voltage exceeds the predetermined limit value, wherein the actuation signal is used to switch off the treatment device, and wherein step size voltages that are greater than the predetermined limit value pose a safety hazard to persons near the treatment device.

11. The method of claim 10, wherein the comparing of the value indicative of the step size voltage to the predetermined limit value is performed by an operational amplifier, and wherein the actuation signal is output by a microprocessor.

12. The method of claim 10, wherein the value indicative of the step size voltage is measured between two measuring electrodes disposed at distal ends of applicators.

13. The method of claim 12, wherein the measuring electrodes measure a voltage field located laterally to the right or left in relation to the direction of travel of the treatment device.

14. The method of claim 12, wherein the measuring electrodes are arranged at a minimum distance from one another, and wherein the minimum distance is 60 cm apart in the direction of travel of the treatment device.

15. A set of processor-executable instructions stored on a processor-readable medium, wherein execution of the set of processor-executable instructions causes a monitoring device for monitoring a treatment device for treating plants to perform operations including:
detecting a value indicative of a step size voltage of the treatment device;
comparing the value indicative of the step size voltage to a predetermined limit value; and
outputting an actuation signal when the step size voltage exceeds the predetermined limit value, wherein the actuation signal is used to switch off the treatment device, and wherein step size voltages that are greater than the predetermined limit value pose a safety hazard to persons near the treatment device.

16. The set of processor-executable instructions of claim 15, wherein the comparing of the value indicative of the step size voltage to the predetermined limit value is performed by an operational amplifier, and wherein the actuation signal is output by a microprocessor.

17. The set of processor-executable instructions of claim 15, wherein the value indicative of the step size voltage is measured between two measuring electrodes disposed at distal ends of applicators.

18. The set of processor-executable instructions of claim 17, wherein the measuring electrodes measure a voltage field located laterally to the right or left in relation to the direction of travel of the treatment device.

19. The set of processor-executable instructions of claim 17, wherein the measuring electrodes are arranged at a minimum distance from one another, and wherein the minimum distance is 60 cm apart in the direction of travel of the treatment device.

20. A monitoring device for monitoring a treatment device for treating plants, comprising:
an input lead coupled to a measuring electrode, wherein the measuring electrode is disposed at a distal end of an applicator of the treatment device, and wherein a value indicative of a step size voltage is received onto the input lead;
a comparator that compares the value indicative of the step size voltage to a predetermined limit value; and
a microprocessor that outputs an actuation signal when the step size voltage exceeds the predetermined limit value, wherein the actuation signal is used to switch off the treatment device, and wherein step size voltages that are greater than the predetermined limit value pose a safety hazard to persons near the treatment device.

21. The monitoring device of claim 20, wherein the step size voltage is indicative of a voltage field located laterally to the right or left in relation to the direction of travel of the treatment device.

22. The monitoring device of claim 20, wherein the value indicative of the step size voltage is measured between the measuring electrode and a second measuring electrode, and wherein the second measuring electrode is disposed at a distal end of a second applicator of the treatment device.

23. The monitoring device of claim 22, wherein the measuring electrode and the second measuring electrode are arranged at a minimum distance from one another, and wherein the minimum distance is 60 cm apart in the direction of travel of the treatment device.

24. The monitoring device of claim 20, wherein the monitoring device is mounted on a self-propelled agricultural machine.
